(19) United States
(12) Patent Application Publication
(10) Pub. No.: US 2004/0199894 A1
(43) Pub. Date: Oct. 7, 2004

(54) Interconnect structure for electrical devices

(76) Inventor: Robert C. Klein JR., Macungie, PA (US)

Correspondence Address: Pepper Hamilton LLP, 50th Floor, One Mellon Center, 500 Grant Street, Pittsburgh, PA, 15219, US

(21) Appl. No.: 10/625,787

(22) Filed: Jul. 23, 2003

Related U.S. Application Data
(60) Provisional application No. 60/398,153, filed on Jul. 23, 2002.

(51) Int. Cl. G06F 17/50; H03K 17/693; H03K 19/00

(52) U.S. Cl. 716/17; 716/12

(57) ABSTRACT

A toroidal interconnect structure is continuous, symmetrical, and non-breaking for the connection of logic and other resources in a semiconductor or other device. The toroidal interconnect structure allows logical and electrical components that physically are implemented in two-dimensional silicon to be organized and connected in a continuous, homogeneous, symmetrical and non-breaking three-dimensional fashion. Instead of connecting components to their nearest neighbors, the connections in the toroidal interconnect skip adjacent rows and columns of interior components and connect directly to components that are physically two rows or columns away. By continuing to skip rows or columns across the device and eventually looping back and connecting the remaining “skipped” components, the continuous, non-breaking connection path is created.

### CLAIM OF PRIORITY

This application claims priority to, and incorporates by reference in its entirety, the U.S. provisional patent application No. 60/398,153, filed Jul. 23, 2002.

### FIELD OF THE INVENTION

This invention relates generally to an improved interconnect structure for use in fields that incorporate semiconductor devices. More specifically, it relates to a programmable interconnect structure that is continuous, symmetrical, and non-breaking for the connection of logic and other resources in a semiconductor device. The principles in this improved interconnect structure may also be applied to devices other than semiconductor devices including, but not limited to, devices used in electrochemical neural networks, and nano-technology networks, such as molecular and atomic level components.

### BACKGROUND OF THE INVENTION

Various interconnect structures have been used in semiconductor devices such as Field Programmable Gate Arrays (FPGAs) and Complex Programmable Logic Devices (CPLDs or simply PLDs). Typically, the interconnect structure in such devices is comprised of a hierarchy of programmable, segmented routing resources. Prior to programming (“configuring”) the device, the routing resources are unconnected and uncommitted to any given function. Upon configuration, the individual segments of the interconnect structure are connected through programmable contact points to various electrical sources and destinations within the device. This forms the logical and electrical interconnect for the function(s) embodied in the device.

Conventional CPLDs and FPGAs can typically be programmed to implement a variety of functions. To support this variety of functions, interconnect structures within these devices must be robust and highly flexible. As a result, the programmable interconnect (or, as it is known to those skilled in the art, “the routing resources”) of such devices consumes a large percentage of the physical device area. However, typical applications for these devices consume only a small portion of these routing resources. The result of this inefficiency is wasted silicon area, which increases unit costs and power requirements while decreasing reliability.

Another significant problem with the interconnect structures of conventional CPLDs and FPGAs are limitations on the placement and connectivity of complex functions within the device. Assuming that a designer or a compiler can densely pack the logic associated with a complex function into an available area of the logic fabric, the routing resources may not be sufficient to efficiently connect the complex function together or to connect it to the rest of the system. In order to compensate for this phenomenon, which is known to those skilled in the art as “routing congestion,” the tools used to implement designs in programmable logic devices intentionally use sparse logic packing techniques and, in some cases, replicate logic. Such packing techniques and replication of logic further increase die size, cost and power requirements for the device while lowering its performance.

Contemporary FPGAs employ a complex hierarchy of programmable routing resources including direct connections between adjacent cells, various multi-block-length spanning connections for reaching cells that are further away, and long-lines that span the width and/or height of the devices. The myriad choices this presents to the place and route software tools makes placing and routing logical designs into FPGAs extremely complex and time-consuming. In addition, signal delay increases with each interconnect point in a route. The accumulation of additional signal delays throughout a system negatively affects the overall system performance. In general, the signal propagation characteristics of routing resources within a conventional programmable device are negatively affected by both the physical length of the connection and the number of loads/potential loads upon that connection. These timing and performance tradeoffs further complicate the propagation and routing process.

Another problem with conventional semiconductor interconnect structures is that they do not permit a designer or compiler to easily relocate functions or make other changes once a design has been completed because of the non-continuous, non-homogeneous nature of the interconnect structure. For example, when a datapath function reaches the physical edge of the device, it must change directions; this forces the use of different routing resources than employed in previous stages, causing congestion and impacting the overall performance of the device.

While prior art interconnect structures may be satisfactory for some particular purposes, they do not provide a continuous, symmetrical, and non-breaking interconnect structure for the connection of logic and other resources in a semiconductor device.

### SUMMARY OF THE INVENTION

In view of the foregoing disadvantages inherent in the known types of interconnect structures now present in the prior art, the present invention provides an improved interconnect structure for use in fields including semiconductor devices. The present invention relates to a programmable interconnect structure that is continuous, symmetrical, and non-breaking when used for the connection of logic and other resources in a semiconductor device. The principles in this improved interconnect structure may also be applied outside the field of semiconductor devices to fields including, but not limited to, electro-chemical neural networks, and nano-technology networks including, but not limited to, molecular and atomic level components.

The general purpose of the present invention, which will be described subsequently in greater detail, is to provide a new improved interconnect structure for semiconductor devices. This interconnect structure embodies many of the advantages of the interconnect structures mentioned heretofore and many novel features to result in a new improved interconnect structure for semiconductor devices which is not suggested or taught by interconnect structures of the prior art, either alone or in combination.

In a preferred embodiment of the present invention, an interconnecting element structure includes an array of elements and a plurality of connection path segments wherein each connection path segment links two of the elements. The elements include edge elements and interior elements. The array is substantially arranged in rows of elements and columns of elements. Each segment in a first subset of the connection path segments links one interior element in the array to another interior element in the array, while each segment in a second subset of the connection path segments links an interior element in the array to an edge element in the array. At least a majority of the segments in the first subset do not link interior elements that are nearest neighbors to each other in the array.

Optionally, each segment in a third subset of the connection path segments may link an edge element in the array to an external element. In another option, the connection path segments are arranged such that a group of the segments forms an overall, continuous connection path for at least one of the columns, and the connection path segments are arranged such that a group of the segments forms an overall, continuous connection path for at least one of the rows. In another option, the connection path segments are arranged such that a group of the segments forms an overall, continuous connection path for at least one of the columns, and the connection path segments are arranged such that a group of the segments forms an overall, continuous connection path for at least one of the rows. The overall, continuous connection path for at least one column or row may include an element that is external to the array. Alternatively, the overall, continuous connection path for at least one of the columns may be symmetrical. Also, the overall, continuous connection path for at least one of the rows may be symmetrical.

In an alternate embodiment, at least a majority of the segments in the first subset link alternating interior elements in the array. In an alternate embodiment, the connection path segments are further arranged to provide an overall, continuous connection path for at least one diagonal line of elements in the array. The connection path for at least one of the diagonal lines may be symmetrical.

In alternate embodiments, the elements can be either semiconductor logic elements or nodes in a neural network. In addition, the segments can be used to transfer data, one or more commands and/or one or more addresses to the elements. In an optional embodiment, the connection path segments include electrically conductive busses.

In an optional embodiment, the structure may include an electrically conductive bus that delivers one or more of data, commands and addresses to the connection path segments.

In a further embodiment, a conductive structure includes an array of elements and a plurality of connection path segments. Each connection path segment links two of the elements, which include edge elements and interior elements. The array is substantially arranged in rows of elements and columns of elements, and no connection path segment links one edge element in a row or column of the array to another edge element in the same row or column of the array.

In a further embodiment, a conductive structure includes a symmetrical array of elements and a plurality of connection path segments. Each connection path segment links two of the elements, and each segment that links one interior element in the structure to another interior element in the structure has a length that is at least as long as the distance between three elements in the array.

There are many ways in which this improved interconnect structure could be implemented. One such way is what will hereafter be referred to as a toroidal implementation. The toroidal descriptor is simply a way of visualizing the present invention. Other visualizations, for example spherical or cubic, could also be applied. These visualizations may or may not directly follow the instruction and data flow as described for the toroidal implementation but would be considered by those skilled in the art to encompass the continuous, symmetrical and non-breaking characteristics of the described toroidal implementation. The present invention is therefore not limited to the toroidal descriptor.

The toroidal interconnect allows logical and electrical components (herein called “Processing Elements” or “PEs”, although other logical and functional blocks may be employed, and this language should not be regarded as limiting) that are physically implemented in a two-dimensional semiconductor device to be organized and connected in a continuous, homogeneous, symmetrical and non-breaking 3-dimenional fashion. Instead of connecting PEs to their nearest neighbors (as would be expected/intuitive for maintaining shortest path lengths and therefore delay times), the connections in the toroidal interconnect skip adjacent rows and columns of PEs and connect directly to the row or column of PEs that is physically two rows/columns away. By continuing this row/column skipping gambit across the device (and eventually looping back and connecting the remaining “skipped” PEs), a continuous, non-breaking connection path is created. The System Bus allows information and data to/from on-chip or external functional blocks to be fed into the continuous logic fabric created by the toroidal interconnect. This enables external data, control, configuration, and status information to be passed into and out of the logic fabric without disrupting the continuous, toroidal datapath(s).

In these respects, the improved interconnect structure for semiconductor devices according to the present invention substantially departs from the conventional concepts and designs of the prior art. In so doing, an apparatus primarily developed for implementing a continuous, symmetrical, and non-breaking interconnect structure for the connection of logic and other resources in semiconductor devices is provided.

In addition to improving semiconductor devices, the principles embodied in the present invention apply equally well to structures outside the pure semiconductor arena. Electro-chemical neural networks that simulate artificial intelligence also rely on and have limitations related to their interconnect structure. In this case, tagged chemical messengers are routed through a medium to receptor cells. Information flows from cell to cell through this routing medium. The chemical messenger approximates an instruction in an FPGA, while the input to and the output from each cell in the neural network approximate the input and output data to and from a programmable operation in the FPGA. The ability to perform these operations in a continuous, symmetrical and non-breaking mode may be of critical importance, depending upon the application. The principles of the present invention apply directly to this need.

With the advent of nano-technology, simple transistor-like circuits have been demonstrated at both the molecular and atomic levels. As this technology matures, more complex circuits are fabricated. The obvious advantages of reduced size, power and leakage currents can eventually bring this technology to the forefront of integrated circuit development. In the purest sense, these circuits are not classified as semiconductor devices because the operational physics at the microscopic level differs between nano-technology devices and semiconductor devices. However, the interconnect principles of the present invention apply equally to these new structures.

There have thus been outlined, rather broadly, the more important features of the invention in order that the detailed description thereof may be better understood, and in order that the present contribution to the art may be better appreciated. There are additional features of the invention that will be described hereinafter.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

### BRIEF DESCRIPTION OF THE DRAWINGS

FIG. 1 is a general block diagram that illustrates a preferred embodiment of the three-dimensional interconnect structure realized in a two-dimensional medium. An eight-row by eight-column array is shown as an illustrative example.

FIG. 2 depicts a three-dimensional conceptual view of the toroidal and system bus connections.

### DETAILED DESCRIPTION OF THE INVENTION

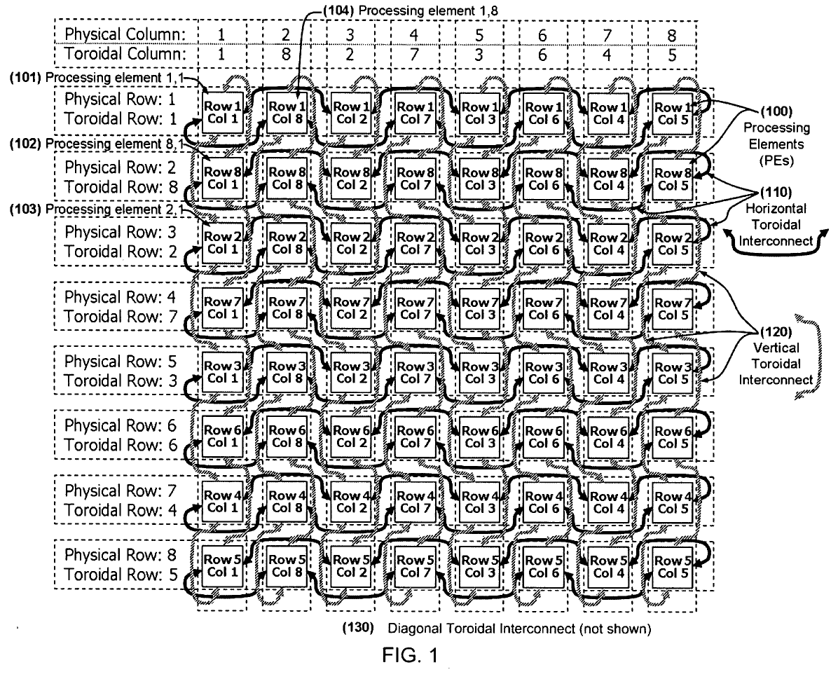

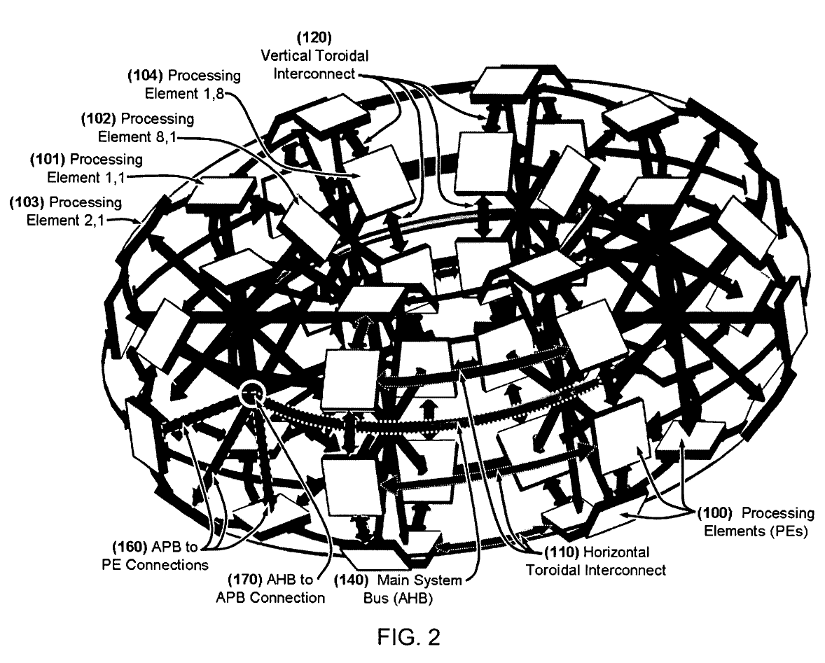

Turning now descriptively to the drawings, in which similar reference characters denote similar elements throughout the views, the attached figures illustrate an improved interconnect structure for use in semiconductor devices, which includes the primary interconnect structure including horizontal rows 110, vertical rows 120, and diagonal rows 130. System-level busses 140 and 150 are also provided to link the rows and columns, respectively. The interconnect structure may allow logical and electrical components that are physically implemented in two-dimensional silicon to be organized and connected in a continuous, homogeneous, symmetrical and non-breaking “three-dimensional” fashion. The logical and electrical components are called “Processing Elements” or “PEs” 100 herein, although other logical and functional blocks may be employed within the scope of the invention. Instead of connecting PEs 100 to their nearest neighbors (as would be intuitive for maintaining shortest path lengths and therefore delay times), the connections in the toroidal interconnect may skip adjacent rows and columns of PEs 100 and connect directly to a row or column of PEs 100 that is physically at least two rows/columns away. By continuing this row/column-skipping gambit across the device (and eventually looping back and connecting the remaining “skipped” PEs 100), the continuous, non-breaking connection path may be created. As illustrated in FIG. 2, this structure is referred to herein as “toroidal” to reflect its effective operation as a continuous, non-breaking, symmetrical logic structure. In addition, although FIGS. 1 and 2 illustrated the edge elements connecting to nearest neighbors and looping back into the structure, the present invention includes an embodiment where one or more elements are left “open,” such as with pins, where the loop may be completed by connecting an external signal path to the structure.

The System Bus structure 140 and 150 may allow information and data that is sent to or from on-chip or external functional blocks to enter into the continuous logic fabric created by the toroidal interconnect structure. This may permit external data, control, configuration, and status information to be passed into and out of the logic fabric without disrupting the continuous toroidal datapath(s).

The toroidal interconnect may be used to connect an array of logical and/or electrical functions in a semiconductor device. While conventional methods seek to limit physical connection lengths and inter-PE signal propagation delays by connecting a PE to the closest neighboring PEs in the device, the toroidal interconnect may simulate a three-dimensional interconnect structure not by connecting to adjacent PEs 100, but rather by directly connecting every other row/column (in effect “skipping” rows and columns of PEs 100) as the interconnection matrix flows across the physical plane of the semiconductor device. For example, processing element 1,1 101 may be physically connected by a vertical toroidal connection 120 to processing element 2,1 103. In the embodiment depicted in FIG. 1, processing element 2,1 103 is located two rows away from processing element 1,1 101. When the interconnect structure reaches the physical edge of the device, the connections simply reverse direction and continue back across the device, skipping rows/columns as before, until the first PE row/column is attached to the last row/column. In FIG. 1, the vertical toroidal connection 120 between processing element 8,1 102 and processing element 1,1 101 and the horizontal toroidal connection 110 between processing element 1,8 104 and processing element 1,1 101 are examples of edge connections between the first and last rows/columns in a device. In an alternate embodiment, the interconnect structure is such that every third row and/or every third column, or other numbers of skipped rows or columns, are interconnected.

In the present invention, the toroidal interconnect structure may have x-direction (referred to herein as “horizontal” or “row”) datapaths 110 and y-direction (referred to herein as “vertical” or “column”) datapaths 120. In addition, the toroidal interconnect structure may have a diagonal, or effective “top left toward bottom right,” datapath 130 that is also toroidal in nature. Other potential structural and functional variations may include providing a similar toroidal interconnect along other diagonal paths, skipping multiple rows/columns, or simply creating the toroidal interconnect in fewer directions than is described herein (for example, a column-based, “vertical-only” toroidal interconnect.) Note that rows and/or columns are not necessarily skipped at edge elements, as an edge element may loop back to its nearest neighbor. In an alternate embodiment, a direct connection may be added to physically adjacent PEs 100 (in addition to the row/column skipping toroidal interconnect); such connections, viewed conceptually from the point of view of the toroidal connection plane, actually “jump across” the toroid to a cell that is on the opposite side of the toroid. For example, if there are “N” cells in the toroid, such a direct connection would connect cell “n” to cell “n+(N/2).” Such connections could be exploited for signals that need to travel a “long distance” from a logical standpoint, but would do so over very fast “local” connections.

In FIG. 1, the terms “physical row” and “physical column” refer to the placement of a row or column, respectively, in a two-dimensional device layout. For example, the first physical row may be the row of PEs 100 that are physically located at the top of the physical media. Sequentially subsequent physical rows may be adjacent to and below preceding physical rows. Likewise, physical columns may be arranged from left to right, where the first physical column is the leftmost column in the physical device. Other embodiments and orientations are possible within the scope of the invention.

In FIG. 1, the terms “row in toroid” and “column in toroid” refer to the placement of a row or column, respectively, in the three-dimensional representation embodied in a two-dimensional device layout. For example, the first row in the toroid may be the row of PEs 100 physically located at the top of the physical media. A sequentially subsequent row in the toroid may be physically at least two rows below the preceding row in the toroid until an edge of the two-dimensional device is reached. At this point, sequentially subsequent rows in the toroid may be the “skipped” rows in the device ordered from the bottom of the device to the top. Likewise, columns in a toroid may be ordered by starting from the leftmost row, selecting every other row until the edge of the physical device is reached, and then selecting the “skipped” rows from right to left. Other embodiments and orientations are possible within the scope of the invention.

The System Busses, which preferably include a primary or row bus 140 and a secondary or column bus 150, may permit information and data that is sent to/from on-chip or external functional blocks to be fed into the continuous logic fabric created by the toroidal interconnect structure. The System Busses 140 and 150 may enable external data, control, configuration, and status information to be passed into and out of the logic fabric without disrupting the continuous toroidal datapath(s). The System Busses 140 and 150 may have a classic microprocessor bus structure, such as ones familiar to those skilled in the art. The System Busses 140 and 150 may be similar to those employed in many system semiconductor devices including Central Processing Units (CPUs), Embedded Microcontrollers (μCs), Digital Signal Processors (DSPs) and most Application-Specific Integrated Circuits (ASICs). Each bus may include address, data, and control signals. The address signals may be used to decode one or more of a plurality of devices and/or locations on the System Busses 140 and 150 that are expected to respond to or supply data to the bus in a given system cycle. Data signals may denote the actual information to be transferred over the bus. The control signals may include such signals as read/write (RD/WR), clock (CLK), and RESET, and they may be used for supervisory and/or timing purposes. The many potential sources and destinations for the signals on the System Busses 140 and 150 may require the need for physically long, robust connections and additional buffering and/or drivers for the most heavily loaded signals. Since all logical and electrical function blocks attached to the System Busses 140 and 150 share these connections, a supervising program, processor, or state machine may be employed to determine which blocks send/receive data and in which order. The supervising program, processor, or state machine may also arbitrate simultaneous requests for the use of resources in order to avoid conflicts or “bus contention”.

In an embodiment, the System Busses 140 and 150 may use the ARM Microprocessor Bus Architecture (AMBA) as specified in the ARM AMBA manual (Doc No: ARM IHI-0011A, Issued: May 1999 by ARM Holdings plc, 90 Fulbourn Road, Cambridge CB1 9NJ, UK) incorporated herein by reference. Both the AHB (“High-performance Bus”) 140 and the APB (“Peripheral Bus”) 150 versions of the AMBA may be used. While the AHB 140 is preferably used chip-wide, one APB 150 maybe used for each column of PEs 100. The column may be addressed/activated by address information carried on the AHB 140. Information (configuration data, status, etc.) and data may be passed between an on-chip microcontroller and the individual PEs 100 through the System Bus structure 140 and 150. The AMBA System Bus 140 and 150 that is employed in an embodiment of the present invention is exemplary of one of many such system-level and/or microprocessor bus structures that may be used for the System Bus 140 and 150. Those skilled in the art will recognize the address, data, and control signals that constitute a System Bus 140 and 150 according to the present invention.

In a preferred embodiment of the present invention, each PE 100 may be connected to the System Busses 140 and 150 through a column APB 150 via an APB to PE connection 160. All PEs 100 within a column may share the address, data, and control signals of the APB 150 associated with that column. The address signals in the APB 150 may determine which PE 100 (and which data, configuration bits, or memory location within it) is the source or destination for the information contained in the data and control signals of the APB 150. Each individual column APB 150 may be selectively connected to the AHB 140 through additional decoding of the address signals via an AHB to APB connection 170. The column APBs 150 may also serve as the connections to other system resources such as on-chip bulk memory blocks, input/output pins, and serial communications modules. Any configuration information needed by these other on-chip resources may also be sent and read-back across the column APBs 150.

The toroidal interconnect may create three potential datapath sources and three destinations for each PE 100, in addition to the APB 150 associated with the PE 100 and self-feedback. In the three-dimensional toroidal interconnect plane, the potential inputs may be from the PE above, the PE to the left, and the PE diagonally up and to the left from the PE 100 under consideration. The data source for the PE 100 may be selected from one or more of these potential source PEs, the associated APB 150, or self-feedback and maybe fed into the PE 100 via multiplexers that are controlled by the configuration of the PE 100. Although the terms “above”, “to the left of”, etc. are used, these relationships may be based on the 3-dimensional toroidal interconnect plane, in the physical device, these cells may actually be removed one row or column from the PE 100 under consideration.

In the three-dimensional toroidal interconnect plane, each PE 100 may potentially output data to the PE below, the PE to the right, and the PE diagonally down and to the right of the PE 100 under consideration. The output destination(s) for the PE 100 may be one or more of these potential destination PEs, the associated APB 150, or self-feedback. The PE 100 may drive one, some, or all of these potential destinations. The proper destination may be selectively driven by the configuration of the PE 100. Although the terms “below”, “to the right of”, etc are used, these relationships may be based on the 3-dimensional toroidal interconnect plane; in the physical device, these cells may actually be removed one row or column from the PE 100 under consideration.

In an embodiment, the toroidal interconnect structure as described herein may employ PEs 100 as the logical or electrical functions or entities that are connected. In practice, the concept of the toroidal interconnect structure may be applicable to and beneficial across a wide range of logical and/or electrical function blocks. Such function blocks may include, but are not limited to:

1.) Look-up table (LUT)-based Configurable Logic Elements or CLEs (SRAM, Flash, PROM, EPROM, EEPROM, and/or antifuse-based CLEs);

2.) Memory blocks;

3.) CISC and/or RISC processor blocks;

4.) Sum-of-Product and/or Product-of-Sum Programmable Array Logic (“PAL”) type blocks;

5.) Arithmetic/Logic Units (ALUs); or

6.) Any combinations of the above.

The present invention may realize the toroidal interconnect structure through the skipping of individual rows and/or columns of PEs 100 (or other elements as described above). Alternate embodiments of the present invention may skip multiple rows and/or columns. In another embodiment, variations in the direction and/or number of interconnect resources in the interconnect structure may be employed. The present invention, for descriptive and illustrative purposes, may focus on implementations with bus-type toroidal interconnect traveling left-to-right, top-to-bottom, and diagonally from top-left toward bottom-right. Other possible implementations may reverse the defined directions of one or more of these connections and/or add similar, additional connections to the ones discussed herein.

When electrical energy is first applied to a device employing the toroidal interconnect (i.e., at system “power-up”), all functional blocks that have the capability of driving signals onto the toroidal interconnect may default to high impedance (“High-Z”). This state may be used to minimize power dissipation and prevent multiple sources from attempting to drive the interconnect simultaneously (bus contention). In a typical scenario, an on-chip digital controller, immediately following power-up, may initiate a built-in self test (BIST) that selectively enables the various interconnect segments, drives test data through the interconnect, and verifies the results. The complexity and the thoroughness of the BIST sequence is not specified in this description of the current invention; however, it is expected that such a test would, at a minimum, check for opens (the inability of an interconnect to carry an electrical signal, i.e., a “broken” wire) and shorts (two or more interconnects electrically connected together in an undesired way). Many examples of techniques for such BIST are known to those skilled in the art. After power-on and BIST, an on-chip digital controller (microprocessor, microcontroller, digital signal processor, or state machine) may set the number and type of connections between the individual PEs 100 (and/or other logical and electrical blocks) by writing information to configuration registers. The configuration registers may have outputs that select these routing characteristics. Thus, the on-chip interconnect topology may be set, controlled and modified during device operation by storing new information in these configuration registers. The configuration information may be supplied to the configuration registers (and ultimately to the toroidal interconnect structure) through a general purpose System Bus structure 140 and 150 (as described above in reference to an embodiment of the present invention), a dedicated configuration bus, the toroidal interconnect structure, or any combination of these data-passing structures. In the course of operation of the device, signals traversing the toroidal interconnect maybe individual bits or larger groups of bits (busses) up to and including the entire width or breadth of the device. Most commonly, the toroidal interconnect may be used as a series of application-specific busses, whose widths will be functions of the application(s) at hand. The ability to dynamically change and scale bus-widths as applications and the needs of those applications change is one advantage of the present invention.

The preferred embodiment of the Improved Interconnect Structure is to be realized in a 0.13 micron CMOS digital process with a single poly level and a minimum of seven copper interconnect levels. Input/Output from the chip runs on a three-volt nominal VDD rail, while the interior of the chip runs on a 1.2-volt nominal VDD rail. To those schooled in the industry, this is commonly referred to as “Plain Vanilla” 0.13 micron CMOS. Other processes and voltages are possible, and are included within the scope of the invention.

The manner of usage and operation of the present invention should be apparent to one of skill in the art from the above description. With respect to the above description, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

The foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents falling within the scope of the invention may be employed.

The invention claimed is:

1. A interconnecting element structure, comprising:
an array of elements; and
a plurality of connection path segments, wherein:
each connection path segment links two of the elements;
the elements include edge elements and interior elements;
the array is substantially arranged in rows of elements and columns of elements;
each segment in a first subset of the connection path segments links one interior element in the array to another interior element in the array, while each segment in a second subset of the connection path segments links an interior element in the array to an edge element in the array; and
at least a majority of the segments in the first subset do not link interior elements that are nearest neighbors to each other in the array.

2. The structure of claim 1 wherein each segment in a third subset of the connection path segments links an edge element in the array to an external element.

3. The structure of claim 1 wherein:
the connection path segments are arranged such that a group of the segments forms an overall, continuous connection path for at least one of the columns; and
the connection path segments are arranged such that a group of the segments forms an overall, continuous connection path for at least one of the rows.

4. The structure of claim 3 wherein the overall, continuous connection path for at least one column or row includes an element that is external to the array.

5. The structure of claim 1 wherein at least a majority of the segments in the first subset link alternating interior elements in the array.

6. The structure of claim 1 wherein the connection path segments are further arranged to provide an overall, continuous connection path for at least one diagonal line of elements in the array.

7. The structure of claim 1 wherein the elements are semiconductor logic elements.

8. The structure of claim 1 wherein the elements are nodes in a neural network.

9. The structure of claim 1 wherein the segments transfer data to the elements.

10. The structure of claim 1 wherein the segments transfer one or more commands to the elements.

11. The structure of claim 1 wherein the segments transfer one or more addresses to the elements.

12. The structure of claim 1 wherein the connection path segments comprise electrically conductive busses.

13. The structure of claim 1 further comprising an electrically conductive bus that delivers one or more of data, commands and addresses to the connection path segments.

14. The structure of claim 3 wherein the overall, continuous connection path for at least one of the columns is symmetrical.

15. The structure of claim 3 wherein the overall, continuous connection path for at least one of the rows is symmetrical.

16. The structure of claim 6 wherein the connection path for at least one of the diagonal lines is symmetrical.

17. A conductive structure, comprising:
an array of elements; and
a plurality of connection path segments, wherein:
each connection path segment links two of the elements;
the elements include edge elements and interior elements;
the array is substantially arranged in rows of elements and columns of elements; and
no connection path segment links one edge element in a row or column of the array to another edge element in the same row or column of the array.

18. The structure of claim 17 wherein:
the connection path segments are arranged such that a group of the segments forms an overall, continuous connection path for at least one of the columns; and
the connection path segments are arranged such that a group of the segments forms an overall, continuous connection path for at least one of the rows.

19. The structure of claim 18 wherein the overall, continuous connection path for at least one column or row includes an element that is external to the array.

20. The structure of claim 17 wherein at least a majority of the segments link alternating interior elements in the array.

21. The structure of claim 17 wherein the connection path segments are further arranged to provide an overall, continuous connection path for at least one diagonal line of elements in the array.

22. The structure of claim 17 wherein the elements are semiconductor logic elements.

23. The structure of claim 17 wherein the elements are nodes in a neural network.

24. The structure of claim 17 wherein the segments transfer data to the elements.

25. The structure of claim 17 wherein the segments transfer one or more commands to the elements.

26. The structure of claim 17 wherein the segments transfer one or more addresses to the elements.

27. The structure of claim 17 wherein the connection path segments comprise electrically conductive busses.

28. The structure of claim 17 further comprising an electrically conductive bus that delivers one or more of data, commands and addresses to the connection path segments.

29. The structure of claim 18 wherein the overall, continuous connection path for at least one of the columns is symmetrical.

30. The structure of claim 18 wherein the overall, continuous connection path for at least one of the rows is symmetrical.

31. The structure of claim 21 wherein the connection path for at least one of the diagonal lines is symmetrical.

32. A conductive structure, comprising:
a symmetrical array of elements; and
a plurality of connection path segments, wherein:
each connection path segment links two of the elements;
the elements include edge elements and interior elements; and
each segment that links one interior element in the structure to another interior element in the structure has a length that is at least as large as the distance between three elements in the array.

33. The structure of claim 32 wherein:
the array is substantially arranged in rows of elements and columns of elements;
the connection path segments are arranged such that a group of the segments forms an overall, continuous connection path for at least one of the columns; and
the connection path segments are arranged such that a group of the segments forms an overall, continuous connection path for at least one of the rows.

34. The structure of claim 33 wherein the overall, continuous connection path for at least one column or row includes an element that is external to the array.

35. The structure of claim 32 wherein at least a majority of the segments link alternating interior elements in the array.

36. The structure of claim 32 wherein the connection path segments are further arranged to provide an overall, continuous connection path for at least one diagonal line of elements in the array.

37. The structure of claim 32 wherein the elements are semiconductor logic elements.

38. The structure of claim 32 wherein the elements are nodes in a neural network.

39. The structure of claim 32 wherein the segments transfer data to the elements.

40. The structure of claim 32 wherein the segments transfer one or more commands to the elements.

41. The structure of claim 32 wherein the segments transfer one or more addresses to the elements.

42. The structure of claim 32 wherein the connection path segments comprise electrically conductive busses.

43. The structure of claim 32 further comprising an electrically conductive bus that delivers one or more of data, commands and addresses to the connection path segments.

44. The structure of claim 33 wherein the overall, continuous connection path for at least one of the columns is symmetrical.

45. The structure of claim 33 wherein the overall, continuous connection path for at least one of the rows is symmetrical.

46. The structure of claim 36 wherein the connection path for at least one of the diagonal lines is symmetrical.
